(19) United States
(12) Patent Application Publication
(10) Pub. No.: US 2015/0264840 A1
(43) Pub. Date: Sep. 17, 2015

(54) ELECTRONIC DEVICE

(71) Applicant: Hideyuki Hirota, Tokyo (JP)

(72) Inventor: Hideyuki Hirota, Tokyo (JP)

(73) Assignee: MITSUBISHI ELECTRIC CORPORATION, Tokyo (JP)

(21) Appl. No.: 14/432,937

(22) PCT Filed: Jan. 10, 2013
(86) PCT No.: PCT/JP2013/050310

§ 371 Date: Apr. 1, 2015

(51) Int. Cl. H05K 9/00; H05K 5/03; H05K 5/00

(52) U.S. Cl. CPC H05K 9/002; H05K 5/0004; H05K 5/03

(57) ABSTRACT

There is provided an electronic device including in the internal space of a case formed by combining an upper case member 2 with a lower case member 3, a metal plate 7 that is provided between the upper case member 2 and a substrate 10 so as to cover the surface of the substrate 10 on which connectors 5, 6, 11, and 12 are mounted, and the shield metal plate 7 includes: an elastically shaped part 8 which is brought into contact with a connector housing 5A to bias the substrate 10 toward the lower case member 3; and pressure contact parts 9a and 9b which press against connector housings 11A and 12A in the direction of the lower case member 3.

### TECHNICAL FIELD

The present invention relates to an electronic device including a shield metal plate that shields an electromagnetic wave.

### BACKGROUND ART

Patent Document 1, for example, discloses an EMI (Electromagnetic wave interference) prevention contactor for an interface connector which is used for connection to other electronic devices, and an electronic device which uses the EMI prevention contactor. In order to obtain an effect of shielding an electromagnetic wave, the contactor is integrally formed with: a conductive connector ground contact part which is contacted to a connector ground on a connector side; a conductive frame ground contact part which is contacted to a frame ground provided in a device housing; and a fixing part which fixes the connector ground contact part and the frame ground contact part to a substrate.

### CITATION LIST

### Patent Document

Patent Document 1: Japanese Patent Application Publication No. 2008-171616

### SUMMARY OF THE INVENTION

### Problems to be Solved by the Invention

Conventionally, in the electronic device including a substrate on which an interface connector used to connect the electronic device to other electronic devices is mounted, there has been an EMI prevention structure provided with a shield metal plate that covers the whole of the substrate and that shields an electromagnetic wave by bringing a part of the shield metal plate into contact with a housing of the connector having conductivity.

However, in the conventional one, in assembling the electronic device, the shield plate is fastened with screws, and thus, there is a problem such that a process for providing a screw-fastening structure is necessary, and that the assembly process becomes complex.

Further, because the conventional shield metal plate is not biased in the assembling direction within the electronic device, in a case where the screws are loose due to vibration being applied thereto for a long time, for example, there is a possibility that a gap occurs between the shield metal plate and the configuration within the electronic device in the assembling direction to thereby cause looseness.

When the looseness occurs, there is a possibility of occurrence of abnormal noise due to a contact between the shield metal plate and the configuration within the electronic device in the assembling direction.

In the prior art represented by Patent Document 1, in order to enhance contact force between the contact part and the ground, the connector ground contact part of the EMI prevention contactor and the frame ground contact part are biased toward the ground side. However, the contactor locally provided around the connector cannot be applied to the assembling of the shield metal plate that covers the whole of the substrate, and cannot solve the problem mentioned above.

The present invention has been made to solve the above-described problem, and an object of the invention is to obtain an electronic device that can be assembled with a simple configuration without looseness.

### Means for Solving the Problems

An electronic device according to the present invention includes: a substrate on which a plurality of connectors each having a conductive connector housing are mounted; and a case which has two case members, and houses the substrate in an internal space formed by combining one case member with the other case member, the electronic device including, in the internal space of the case, a shield member that is provided between the one case member and the substrate to cover a surface of the substrate on which the connectors are mounted, and the shield member includes: an elastically shaped part which is brought into contact with a connector housing of any of the plurality of connectors to bias the substrate toward the other case member; and a pressure contact part which pressure-contacts with any of the remaining connector housings in a direction of the other case member.

### Effects of the Invention

According to the present invention, there is an advantageous effect that the electronic device can be assembled with a simple configuration without looseness.

### BRIEF DESCRIPTION OF THE DRAWINGS

FIG. 1 is a perspective view showing an electronic device according to Embodiment 1 of the present invention.

FIG. 2 is an exploded perspective view of the electronic device in FIG. 1.

FIG. 3 is a perspective view showing an internal configuration of the electronic device in FIG. 1.

FIG. 4 is a view showing a substrate having a shield metal plate disposed thereon in Embodiment 1.

FIG. 5 is a sectional view of the electronic device according to Embodiment 1.

FIG. 6 is a view showing an electronic device according to Embodiment 2 of the present invention.

### MODES FOR CARRYING OUT THE INVENTION

In the following, in order to describe the present invention in more detail, embodiments for carrying out the invention will be described with reference to the accompanying drawings.

### Embodiment 1

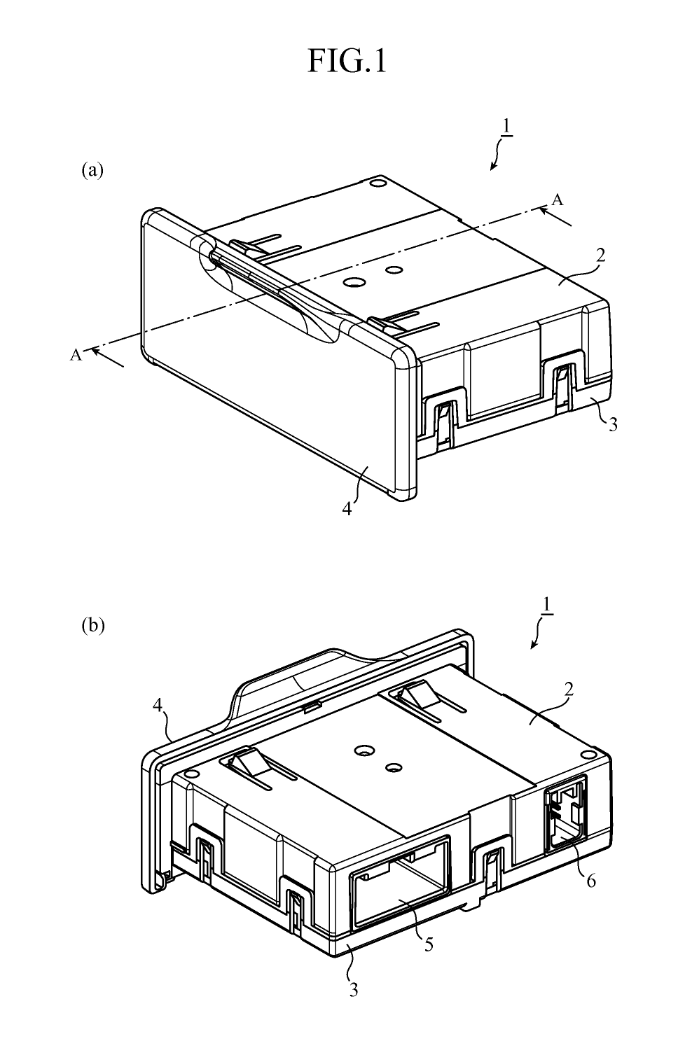

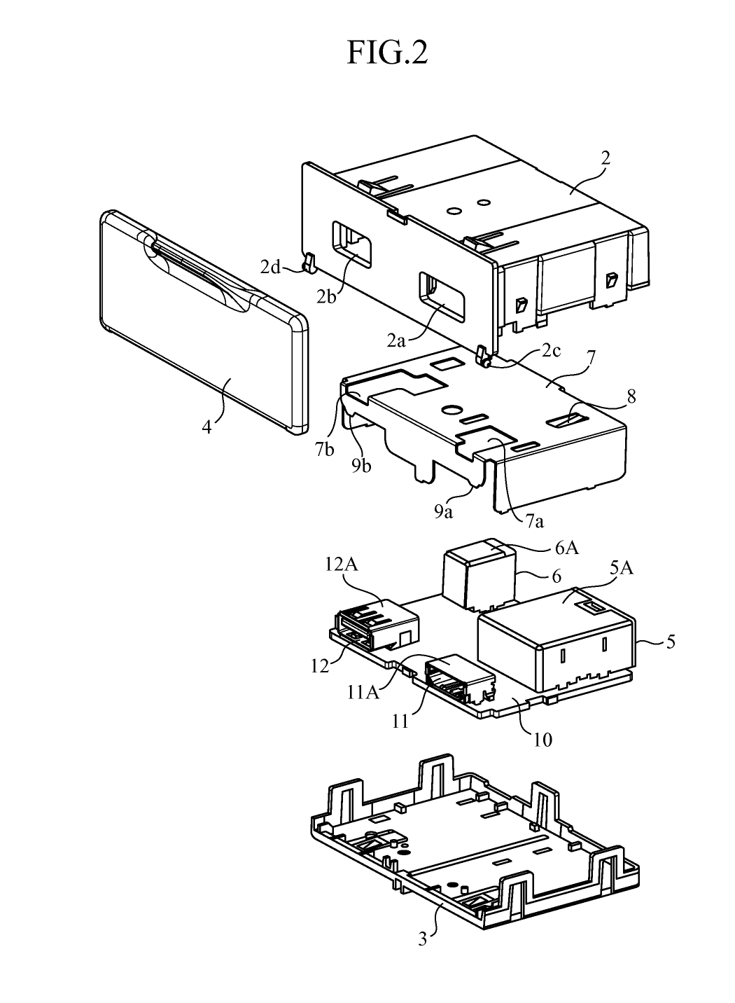

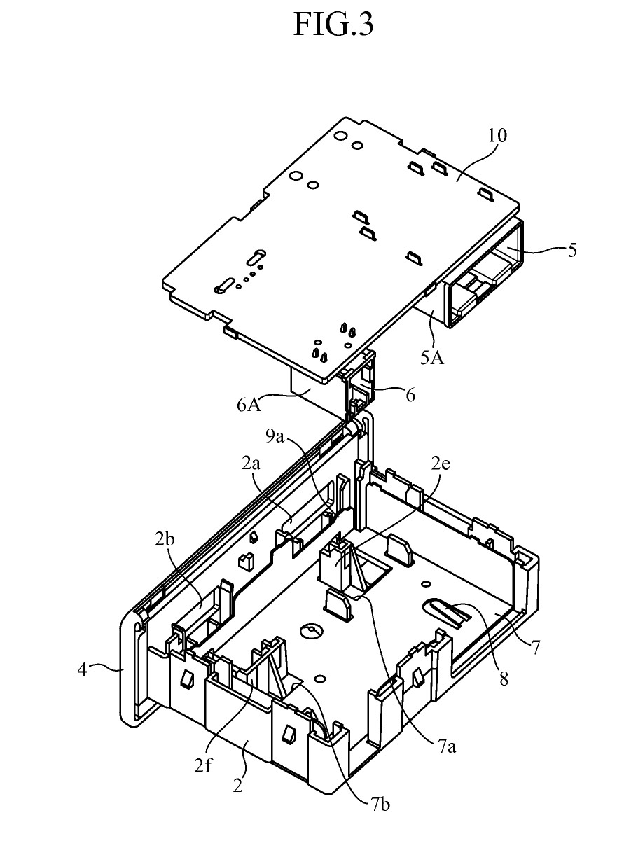

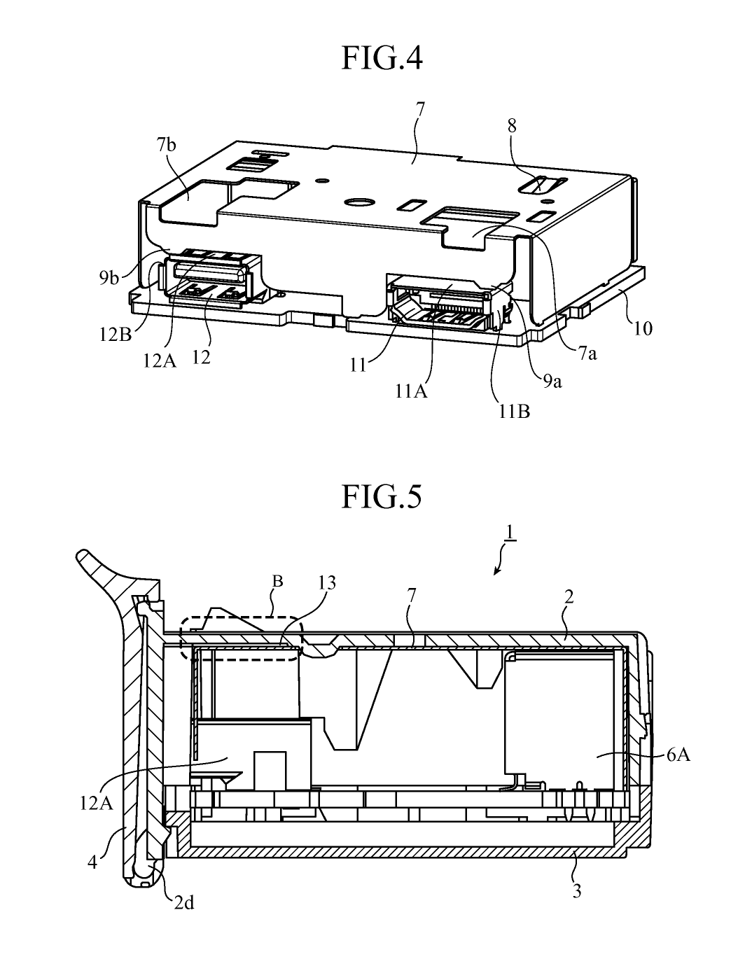

FIG. 1 is a perspective view showing an electronic device according to Embodiment 1 of the present invention. FIG. 1(a) is a perspective view on the front surface side of the electronic device, and FIG. 1(b) is a perspective view on the rear surface side. In addition, FIG. 2 is an exploded perspective view of the electronic device in FIG. 1. FIG. 3 is a perspective view showing an internal configuration of the electronic device in FIG. 1. FIG. 4 is a view showing a substrate having a shield metal plate disposed thereon according to Embodiment 1.

An electronic device 1 according to Embodiment 1 is a vehicle-mounted external-input interface electronic device having an open-close type lid member 4, for example, and as shown in FIG. 1(a), includes a case formed by having an upper case member 2 combined with a lower case member 3, and the lid member 4 attached to the front surface of the upper case member 2.

The upper case member 2 has a rectangular shape with one surface opened as shown in FIG. 2, and has the lower case member 3 combined with the opening part.

Further, on the rear surface of the upper case member 2, each opening of connectors 5 and 6 is exposed as shown in FIG. 1(b). On the front surface of the upper case member 2, opening parts 2a and 2b from which connectors 11 and 12 are exposed are formed as shown in FIG. 2.

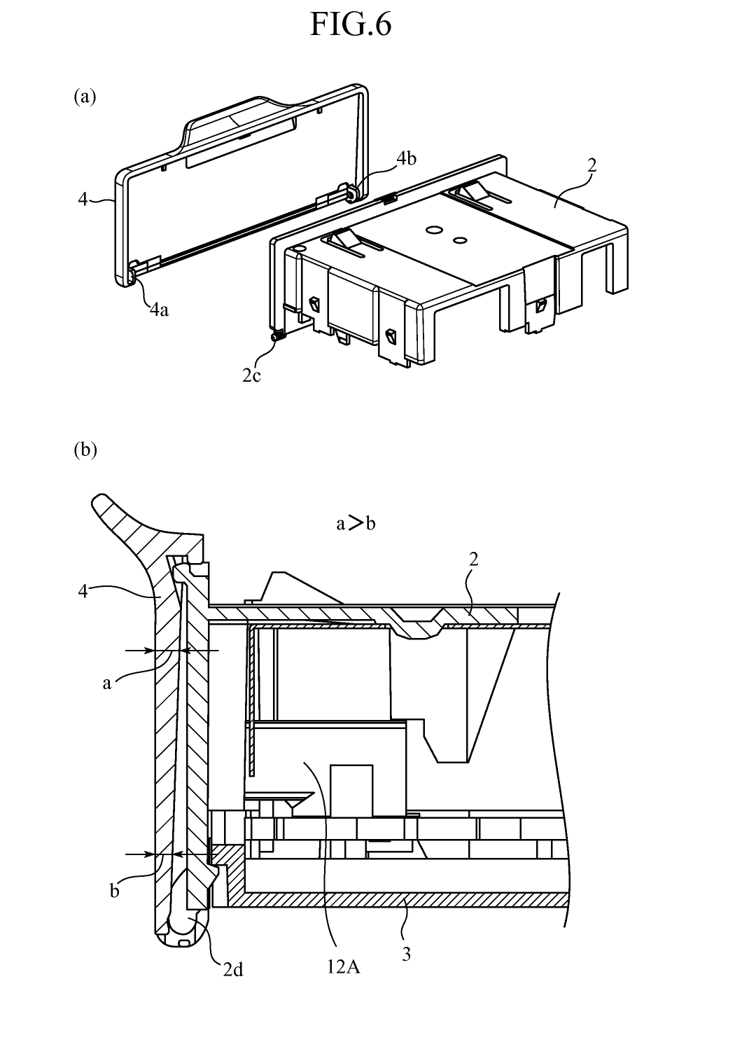

The lid member 4 is the one that is turnably attached to the front surface of the upper case member 2, and protects the connectors 11 and 12 which are exposed from the openings 2a and 2b. In addition, the lid member 4 is formed from a material having flexibility such as a resin; when installing the lid member 4 on the front surface of the upper case member 2, the lid member 4 is bent, and support shafts 2c and 2d are fitted to shaft holding parts (described later with reference to FIG. 6) that are formed at both ends of the lower side of the lid member 4.

In addition, as shown in FIG. 2, a shield metal plate 7 and a substrate 10 are housed in an internal space of a case which is formed by combining the upper case member 2 with the lower case member 3.

The shield metal plate 7 is the one that shields a high-frequency wave radiated from the substrate 10, and is formed by bending end surfaces of a conductive metal plate such that one surface of the plate is opened.

Additionally, on a ceiling surface of the shield metal plate 7, an elastically shaped part 8 is formed. At a lower end of a front surface part of the shield metal plate 7, pressure contact parts 9a and 9b are formed.

Further, as shown in FIG. 2 and FIG. 3, the shield metal plate 7 is disposed between the upper case member 2 and the substrate 10, and is installed to cover a mounted surface of the substrate 10 with the ceiling surface and each side surface.

The connectors 5, 6, 11, and 12 are mounted on the substrate 10. Because of the need for inserting connectors of external connection cables thereinto, the opening parts of connectors 5, 6, 11, and 12 are provided to be exposed from at least a side surface of the case. Therefore, as shown in FIG. 2, the connectors 5, 6, 11, and 12 are disposed at an edge-side side of the substrate 10.

Further, the connectors 5 and 6 are held by conductive connector housings 5A and 6A, and the connectors 11 and 12 are held by conductive connector housings 11A and 12A. The connector housings 5A, 6A, 11A, and 12A are grounded via the substrate 10.

As shown in FIG. 3 and FIG. 4, the elastically shaped part 8 has a spring shape configured by bending downward a part of the ceiling surface of the shield metal plate 7, and its tip portion is brought into contact with the ceiling surface of the connector housing 5A of the connector 5 such that the substrate 10 is biased to the lower case member 3 side.

In addition, as shown in FIG. 3, the upper case member 2 is formed with ribs 2e and 2f that extend from the ceiling surface of the inside of the upper case member 2. When the upper case member 2 is installed, the ribs 2e and 2f pass through through-hole parts 7a and 7b of the shield metal plate 7, and are brought into contact with the connector housings 11A and 12A such that the ribs 2e and 2f regulate movement in the up-and-down direction of the substrate 10. In this case, because the connectors 11 and 12 are positioned below the through-hole parts 7a and 7b as shown in FIG. 4, elastically shaped parts corresponding to the connector housings 11A and 12A cannot be formed.

Accordingly, in the present invention, the pressure contact parts 9a and 9b are provided at the side surface part, not on the ceiling surface part, of the shield metal plate 7. The pressure contact parts 9a and 9b are formed at the lower end of the front-side surface part of the shield metal plate 7, and are projected downward; positions of the lowest ends thereof are slightly lower than the positions of the ceiling surfaces of the connector housings 11A and 12A. Therefore, when the shield metal plate 7 is installed, the pressure contact parts 9a and 9b pressure-contact with the connector housings 11A and 12A in the direction of the lower case member 3.

In this way, the elastically shaped part 8 biases the connector housing 5A, and the pressure contact parts 9a and 9b pressure-contact with the connector housings 11A and 12A; consequently, the substrate 10 is pressed against the lower case member 3 side, and thus, it becomes possible to hold properly the substrate 10 within the case without looseness. Further, because the substrate does not need to be fixed with screws, a screw-fastening step can be omitted from the manufacturing process, and also a complex screw-fastening work becomes unnecessary in the assembling process.

Meanwhile, when the pressure contact parts 9a and 9b pressure-contact with the center parts of the ceiling surfaces of the connector housings 11A and 12A, there is a possibility of crush deforming the ceiling surfaces of the connector housings 11A and 12A.

Therefore, as shown in FIG. 4, the pressure contact parts 9a and 9b may be formed at positions to pressure-contact with the upper end portions of side surfaces 11B and 12B of the connector housings 11A and 12A. With this configuration, pressure-contacting force from the pressure contact parts 9a and 9b comes to be received and supported by the side surfaces 11B and 12B of the connector housings 11A and 12A.

FIG. 5 is a sectional view of the electronic device according to Embodiment 1, and shows a cross section cut along a line A-A in FIG. 1(a). As mentioned above, the positions of the lowest ends of the pressure contact parts 9a and 9b are slightly lower than the positions of the ceiling surfaces of the connector housings 11A and 12A. Therefore, when the pressure contact parts 9a and 9b pressure-contact with the connector housings 11A and 12A, the shield metal plate 7 comes to be bent upward.

When there is no escape for this bending, after the upper case member 2 is installed, the upper case member 2 presses the pressure contact parts 9a and 9b in the installation direction; consequently, the pressure contact parts 9a and 9b come to be excessively pressure-contacted with the connector housings 11A and 12A. In this case, there is a risk of deforming the connector housings 11A and 12A.

Accordingly, as shown by a symbol B in FIG. 5, between the upper case member 2 and the shield metal plate 7, there is provided a clearance 13 for escape of the shield metal plate 7 to be bent due to the pressure contact parts 9a and 9b pressure-contacting with the connector housings 11A and 12A.

Incidentally, in the example of FIG. 5, the clearance 13 is formed between the upper case member 2 and the shield metal plate 7 by providing a concave portion on the ceiling surface of the upper case member 2. Alternatively, the clearance may be formed by bending downward the shield metal plate 7.

As described above, according to Embodiment 1, in the internal space of the case formed by combining the upper case member 2 with the lower case member 3, the electronic device includes the shield metal plate 7 that is provided between the upper case member 2 and the substrate 10 so as to cover the surface of the substrate 10 on which the connectors 5, 6, 11, and 12 are mounted, and the shield metal plate 7 includes: the elastically shaped part 8 which is brought into contact with the connector housing 5A and which biases the substrate 10 toward the lower case member 3; and pressure the contact parts 9a and 9b which pressure-contacts with the connector housings 11A and 12A in the direction of the lower case member 3. With this configuration, the electronic device has a simple configuration that eliminates the need of the screw fastening, and because the substrate 10 can be forcibly biased toward the lower case member 3 side, it is possible to prevent the occurrence of looseness.

In addition, according to Embodiment 1, because the pressure contact parts 9a and 9b pressure-contact with the upper end portions of the side surfaces 11B and 12B of the connector housings 11A and 12A, it is possible to prevent the connector housings 11A and 12A from being deformed by the pressure contacting by the pressure contact parts 9a and 9b.

Further, according to Embodiment 1, between the upper case member 2 and the shield metal plate 7, there is provided the clearance 13 for escape of the shield metal plate 7 bent due to the pressure contact parts 9a and 9b pressure-contacting with the connector housings 11A and 12A. As a result, it is possible to prevent the pressure contact parts 9a and 9b from excessively pressure-contacting with the connector housings 11A and 12A.

### Embodiment 2

FIG. 6 is a view showing an electronic device according to Embodiment 2 of the present invention. FIG. 6(a) shows an upper case member 2 and a lid member 4, and FIG. 6(b) shows a vertical sectional view of the lid member 4 attached to the upper case member 2. In the case of attaching the lid member 4 to the front surface of the upper case member 2, the lower-side side of the lid member 4 is bent to be spread laterally, and support shafts 2c and 2d which are provided at both ends of the lower side of the front surface of the upper case member 2 are fitted to shaft holding parts 4a and 4b formed at both ends of the lower side of the lid member 4. Therefore, when the lid member 4 is uniformly thick, the lid member 4 cannot be satisfactorily bent, which cannot be attached to the front surface of the upper case member 2.

Accordingly, in Embodiment 2, the lid member 4 is configured to have a smaller thickness toward the lower-side side that is attached to the support shafts 2c and 2d. Specifically, as shown in FIG. 6(b), between a thickness a of the upper-side side of the lid member 4 and a thickness b of the lower-side side of the lid member 4, there is a relationship of b<a. This facilitates that the lower-side side of the lid member 4 is easily bent to be expanded laterally.

As described above, according to Embodiment 2, the electronic device includes the lid member 4 that opens and closes the side surface of the case on which the opening parts of the connectors 11 and 12 are exposed, and the thickness of the lid member 4 becomes smaller toward the portion that is turnably attached along the edge side of the side surface of the case. With this configuration, the lid member 4 can be easily attached thereto, and consequently, the electronic device can be easily installed thereto.

In Embodiment 1 and Embodiment 2 described above, there are described the configurations in which the shaft holding parts 4a and 4b are provided in the lid member 4, and the support shafts 2c and 2d are provided on the front surface of the upper case member 2; however, the support shafts may be provided in the lid member 4, and the shaft holding parts may be provided on the front surface of the upper case member 2.

Within the range of the present invention, the present invention may have a free combination of each embodiment, or an arbitrary modification of configuration elements of each embodiment, and an arbitrary omission of configuration elements is possible in each embodiment.

### INDUSTRIAL APPLICABILITY

The electronic device according to the present invention can be assembled with a simple configuration without looseness, and thus, it is suitable for vehicle-mounted electronic devices in which vibration that causes looseness easily occurs due to running of vehicles.

### DESCRIPTION OF REFERENCE NEMERALS AND SIGNS

1 Electronic device
2 Upper case member
2a, 2b Opening
2c, 2d Support shaft
2e, 2f Rib
3 Lower case member
4 Lid member
4a, 4b Shaft holding part
5, 6, 11, 12 Connector
5A, 6A, 11A, 12A Connector housing
7 Shield metal plate
7a, 7b Through-hole part
8 Elastically shaped part
9a, 9b Pressure contact part
10 Substrate
11B, 12B Side surface
13 Clearance.

1. An electronic device comprising:
a substrate on which a plurality of connectors each having a conductive connector housing are mounted; and
a case which has two case members, and houses the substrate in an internal space formed by combining one case member with the other case member,
the electronic device further comprising, in the internal space of the case, a shield member that is provided between the one case member and the substrate to cover a surface of the substrate on which the connectors are mounted, wherein
the shield member includes:
an elastically shaped part which is brought into contact with a connector housing of any of the plurality of connectors to bias the substrate toward the other case member; and
a pressure contact part which pressure-contacts with any of the remaining connector housings in a direction of the other case member.

2. The electronic device according to claim 1, wherein the pressure contact part pressure-contacts with an upper end portion of a side surface of the connector housing.

3. The electronic device according to claim 1, wherein a clearance serving as an escape of the shield member which is bent due to the pressure contact part pressure-contacting with the connector housing is provided between the one case member and the shield member.

4. The electronic device according to claim 1, further comprising a lid member that opens and closes a side surface of the case on which opening parts of the connectors are exposed, wherein
a thickness of the lid member becomes smaller toward a portion that is turnably attached to an edge side of the side surface of the case.
